(19) United States
(12) Patent Application Publication
(10) Pub. No.: US 2014/0307368 A1
(43) Pub. Date: Oct. 16, 2014

(54) ELECTRONIC DEVICE ENCLOSURE

(71) Applicants: HON HAI PRECISION INDUSTRY CO., LTD., New Taipei (TW); HONG FU JIN PRECISION INDUSTRY (ShenZhen) CO., LTD., ShenZhen (CN)

(72) Inventors: WEI-KUANG LIANG, New Taipei (TW); QUAN-GUANG DU, Shenzhen (CN); CHUN TANG, Shenzhen (CN)

(73) Assignees: HON HAI PRECISION INDUSTRY CO., LTD., New Taipei (TW); HONG FU JIN PRECISION INDUSTRY (ShenZhen) CO., LTD., ShenZhen (CN)

(21) Appl. No.: 14/084,837

(22) Filed: Nov. 20, 2013

(30) Foreign Application Priority Data
Apr. 15, 2013 (CN) 2013101286957

(51) Int. Cl. H05K 7/00

(52) U.S. Cl. CPC H05K 7/00
USPC 361/679.01

(57) ABSTRACT

An electronic device enclosure includes base, a display frame, and a locking structure. The base defines two latching holes. The display frame is rotatably secured to the base. The locking structure includes a sliding strip and a resilient member. The sliding strip is attached on the display frame and includes two latching hooks. Each of the two latching hooks is engaged with a flange of each of the latching holes, to prevent the display frame from rotating relative to the base. The resilient member is hung between the display frame and the sliding strip and resiliently deformed, to prevent each of the two latching hooks from disengaging from the flange of each of the two latching holes.

### BACKGROUND

1. Technical Field

The present disclosure relates to electronic device enclosures, and more particularly to an electronic device enclosures with a locking structure.

2. Description of Related Art

A notebook always includes a base and a display secured to the base with hinges. The display is always closed when the notebook is not in use, to prevent foreign matter, such as dust from contaminating a keyboard located on the base. The display is only against the base and may automatically rotate opened while being carried. Therefore, there is room for improvement in the art.

### BRIEF DESCRIPTION OF THE DRAWINGS

Many aspects of the embodiments can be better understood with references to the following drawings. The components in the drawings are not necessarily drawn to scale, the emphasis instead being placed upon clearly illustrating the principles of the embodiments. Moreover, in the drawings, like reference numerals designate corresponding parts throughout the several views.

FIG. 1 is an exploded, isometric view of an electronic device enclosure in accordance with an embodiment.

FIG. 2 is an assembled view of the electronic device enclosure of FIG. 1.

FIG. 3 is an exploded, isometric view of a base and a locking structure of FIG. 1.

FIG. 4 is an isometric view of a sliding strip of FIG. 3.

FIG. 5 is a cross-sectional view of the sliding strip taken along a line V-V of FIG. 4.

FIG. 6 is an enlarged view of a circled portion VI of FIG. 5.

FIG. 7 is an assembled view of the base and the locking structure of FIG. 3.

FIG. 8 is an enlarged view of a circled portion VIII of FIG. 7.

FIG. 9 is an enlarged view of a circled portion IX of FIG. 7.

### DETAILED DESCRIPTION

The disclosure is illustrated by way of example and not by way of limitation in the figures of the accompanying drawings in which like references indicate similar elements. It should be noted that references to “an” or “one” embodiment in this disclosure are not necessarily to the same embodiment, and such references mean at least one.

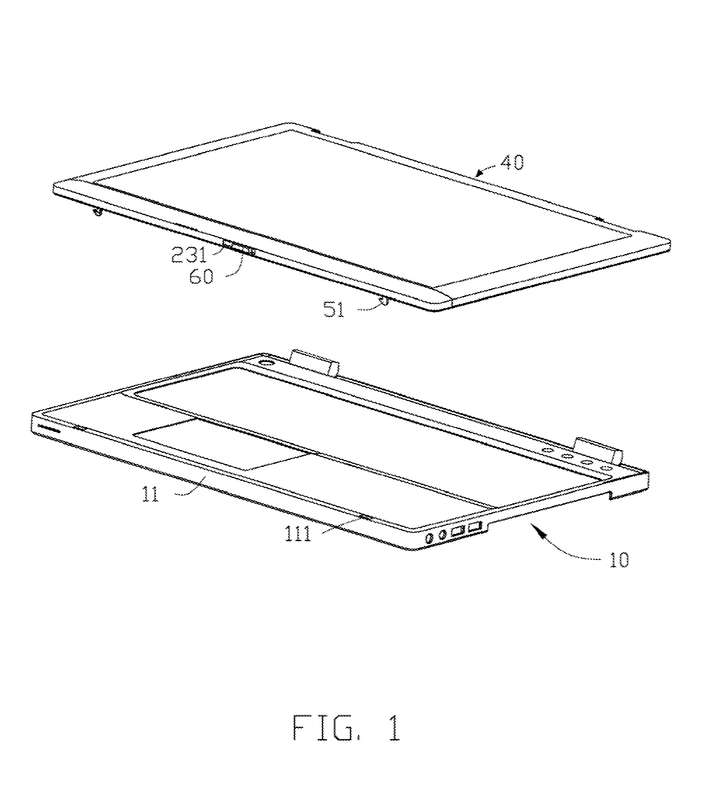

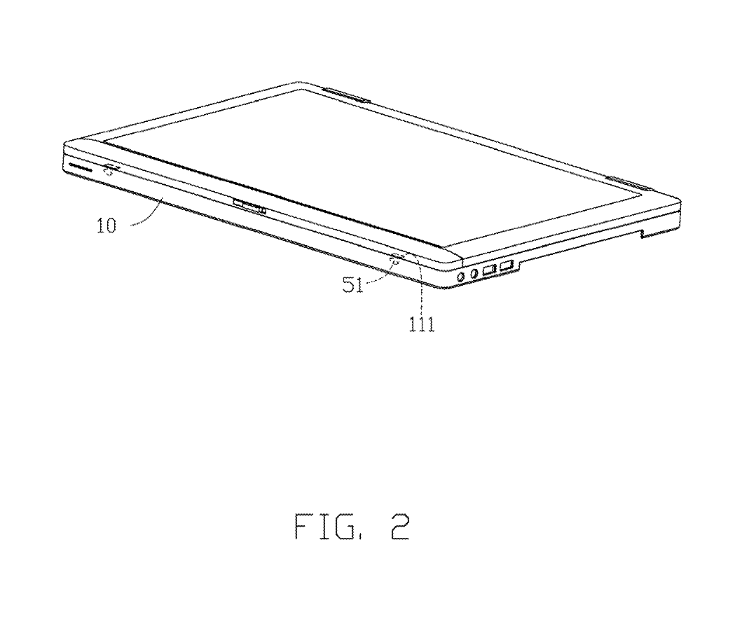

FIGS. 1-3 illustrate an electronic device enclosure in accordance with an illustrated embodiment. The electronic device enclosure includes a base 10, a display frame 40, and a locking structure 80. The electronic device enclosure may be a notebook enclosure, for example.

The base 10 includes a front sidewall 11 and further defines two latching holes 111 adjacent to the front sidewall 11. A line through the two latching holes 111 is substantially parallel to the front sidewall 11.

The display frame 40 is rotatably secured to the base 10 and includes a backboard 20, and a bezel 30 installed on the backboard 20. The backboard 20 and bezel 30 cooperatively clip a monitor (not shown). The bezel 30 defines two through holes 31 corresponding to the two latching holes 111.

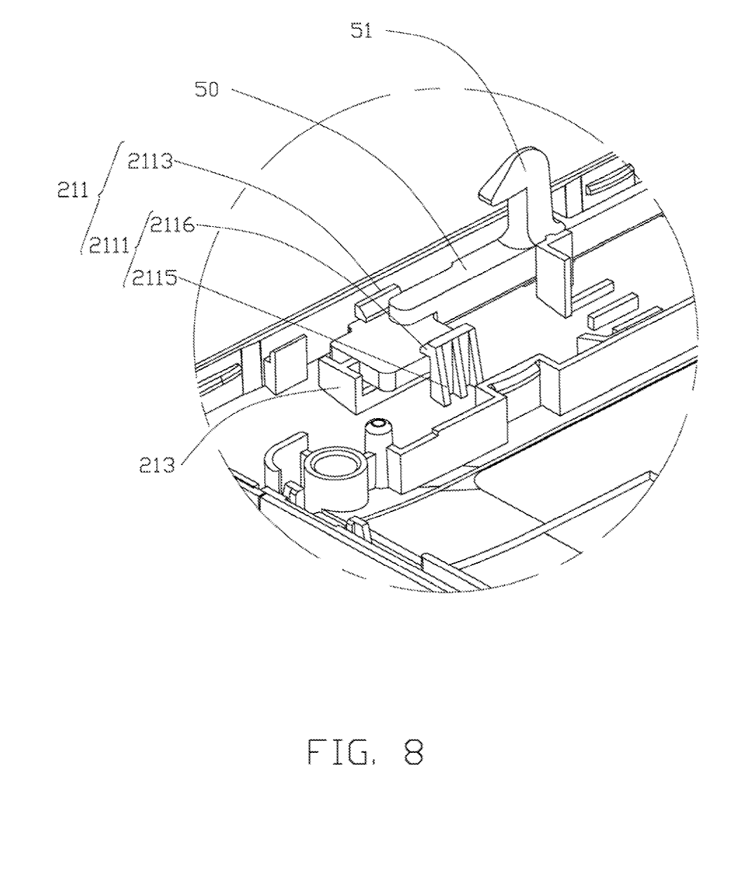

The backboard 20 includes a bottom plate 21 and a front plate 23. The front plate 23 perpendicularly extends from a front edge of the bottom plate 21. The front plate 23 defines a recess 231, and a bottom portion 233 of the recess 231 defines two installation holes 2331 in communication with the recess 231. Two pairs of latching structures 211 (shown in FIG. 8) are located on the bottom plate 21 and located on two opposite sides of the recess 231.

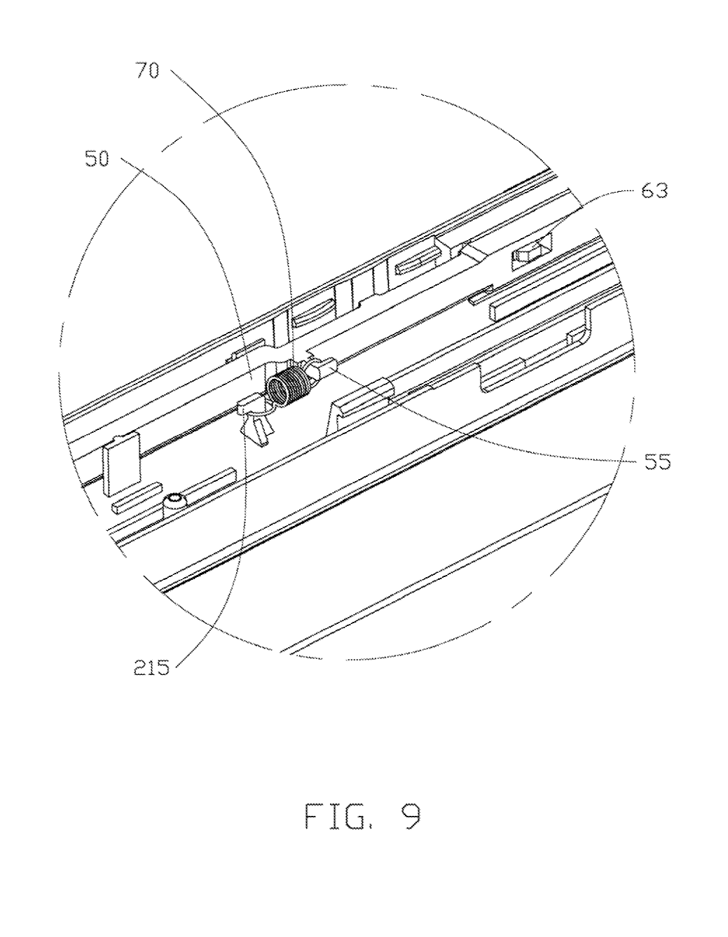

FIGS. 8-9 show that each of the two pairs of latching structures 211 includes a first hook 2111, and a second hook 2113 opposite to the first hook 2111. In one embodiment, the two pairs of latching structures 211 are arranged at four corners of a rectangle. Both of the first hook 2111 and the second hook 2113 include a blocking tab 2115 and a stopping tab 2116 extending from a distal end of the blocking tab 2115. The blocking tab 2115 of the first hook 2111 is substantially parallel to the blocking tab 2115 of the second hook 2113. The stopping tab 2116 of the first hook 2111 has a first extension direction, and the stopping tab 2116 of the second hook 2113 has a second extension direction opposite to the first extension direction. A limiting tab 213 and a first stopper hook 215 (shown in FIG. 9) are located on the bottom plate 21. The limiting tab 213 is located outside of the two pairs of latching structures 211 and adjacent to one of the two pair of latching structures 211. The first stopper hook 215 is arranged between the two pairs of latching structures 211 and adjacent to the one of the two pair of latching structure 211.

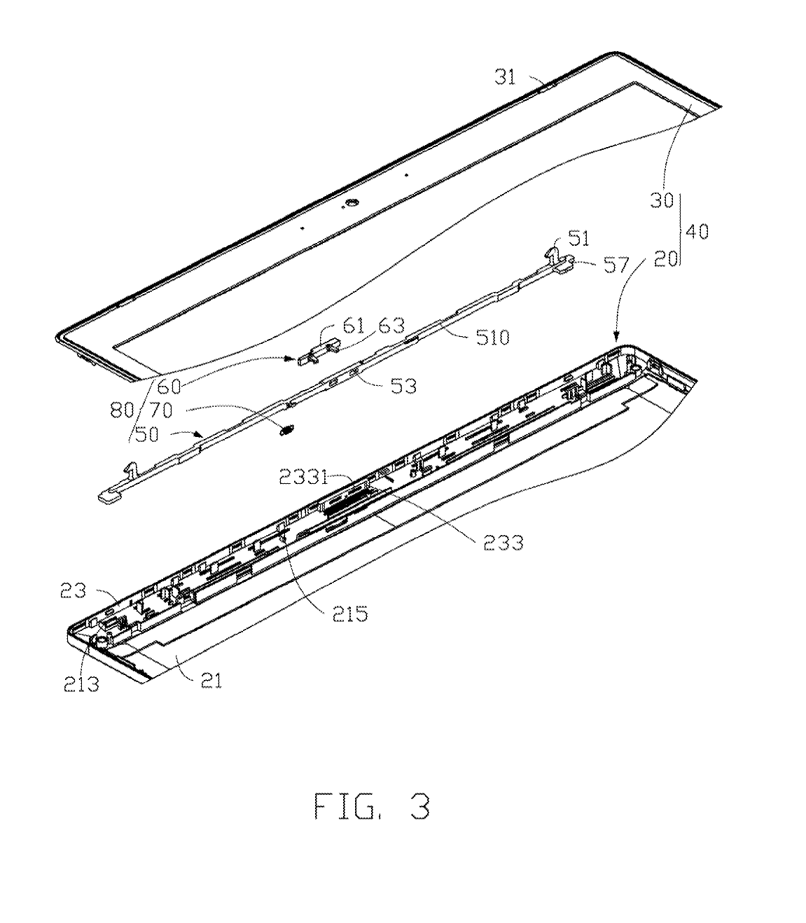

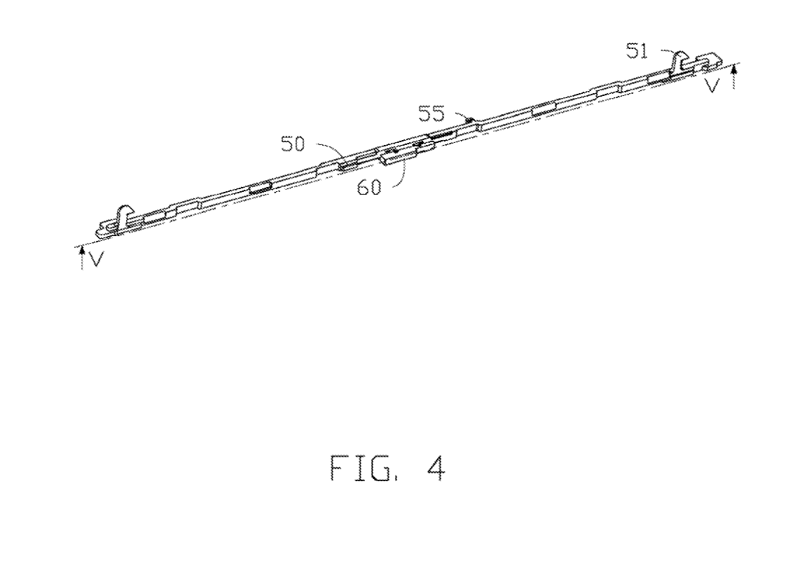

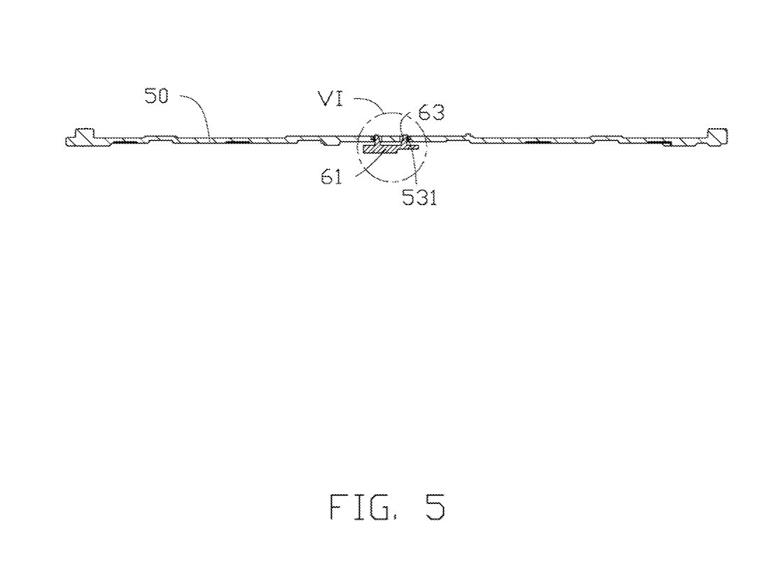

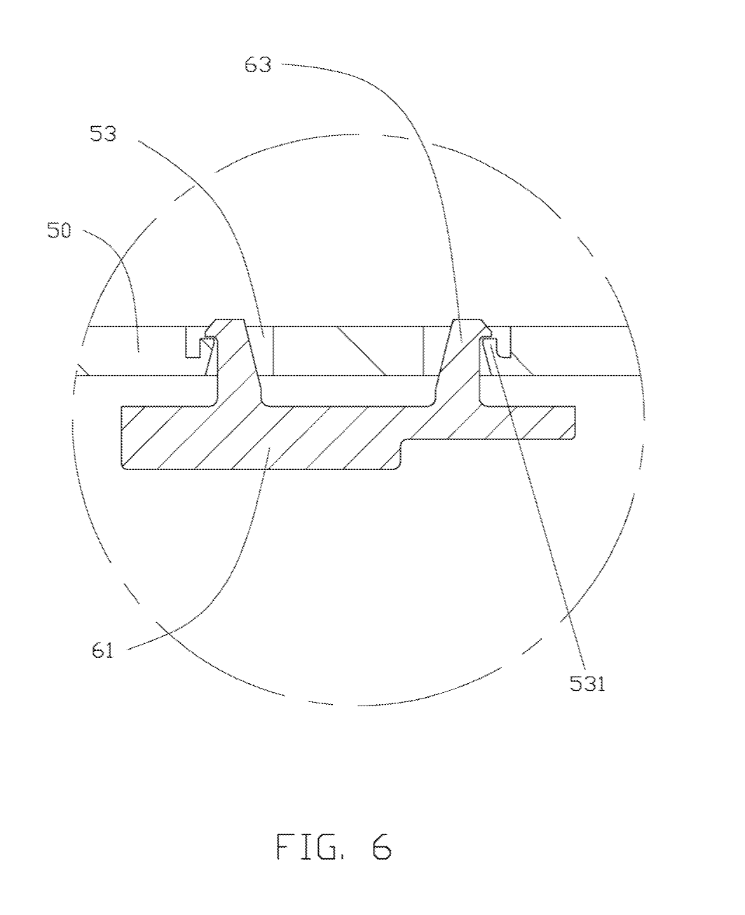

FIGS. 3-6 show that the locking structure 80 includes an elongated sliding strip 50, an actuating member 60, and a resilient member 70. In one embodiment, the resilient member 70 is an extension spring. The sliding strip 50 includes a strip body 510, and two latching hooks 51. The two latching hooks 51 are located on the strip body 510. Each of the two latching hooks 51 is adjacent to each of two opposite ends of the strip body 510. Two receiving holes 53 are defined in a center of the strip body 510 and along a direction that is substantially perpendicular to the front plate 23. Two resisting tabs 531 are located on the strip body 510, and each of the two resisting tabs 531 extends from one sidewall of the two receiving holes 53. The two resisting tabs 531 are located on a first plane, and the two latching hooks 51 are located on a second plane. In one embodiment, the first plane is substantially perpendicular to the second plane. A second stopper hook 55 is located on the strip body 510, corresponding to the first stopper hook 215. Two bearing tabs 57 are located on two opposite ends of the strip body 510, for engaging with the two pairs of latching structures 211.

FIG. 3 shows that the actuating member 60 includes an operating portion 61 and two engaging hooks 63 located on one side of the operating portion 61.

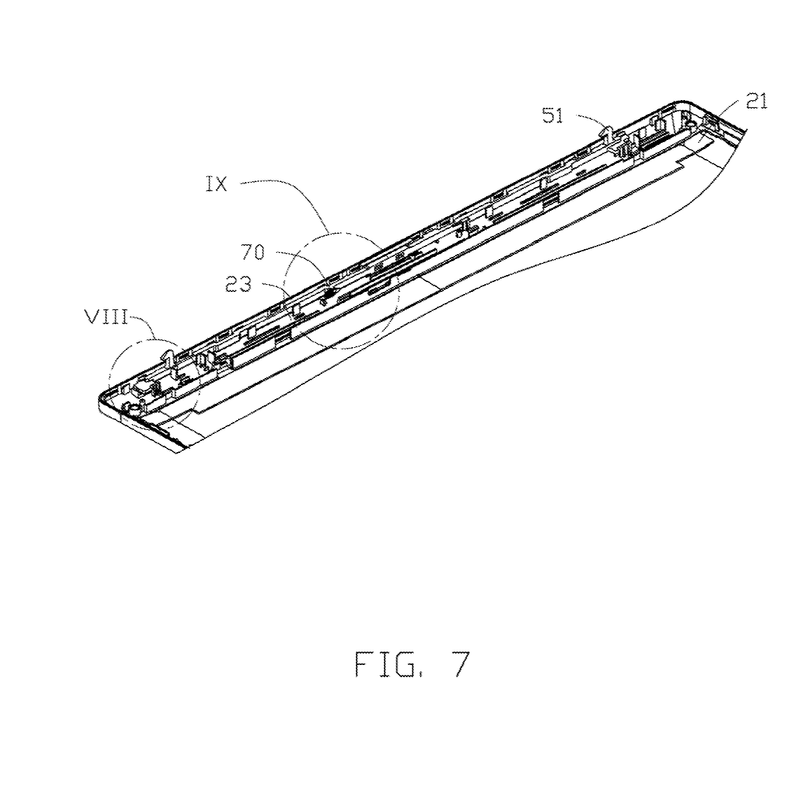

FIG. 7 shows that in assembly of the sliding strip 50, the sliding strip 50 is positioned on the bottom plate 21. Each of the two bearing tabs 57 is positioned between the blocking tabs 2115 of each of the two pairs of latching structures 211 and is engaged with the stopping tabs 2116 of each of the two pairs of latching structures 211. One of the two bearing tabs 57 abuts the limiting tab 213. The sliding strip 50 is slidably attached to the backboard 20.

In assembly of the actuating member 60, each of the two engaging hooks 63 extends through each of the two installation holes 2331 to be engaged in each of the two receiving holes 53. Each of the two engaging hooks 63 is engaged with each of the two resisting tabs 531. The operating portion 61 is received in the recess 231, and a part of the operating portion 61 is exposed out of the front plate 23. A first end of the resilient member 70 is surrounded on the first stopper hook 215, and a second end opposite to the first end of the resilient member 70 is surrounded on the second stopper hook 55. Thus, the resilient member 70 is thereby resiliently engaged between the first stopper hook 215 and the second stopper hook 55.

The bezel 30 is installed on the backboard 20, and each of the two latching hooks 51 extends through each of the two through holes 31.

When the display frame 40 needs to be closed, the display frame 40 is rotated closed to the base 10. The operating portion 61 of the actuating member 60 is pushed to slide along a first direction. The sliding strip 50 also slides in the first direction along with the actuating member 60, until each of the two latching hooks 51 is aligned with each of the two latching holes 111. The display frame 40 is rotated in succession, until each of the two latching hooks 51 is engaged into each of the two latching holes 111. The operating portion 61 is released. The resilient member 70 resiliently rebounds to slide the sliding strip 50 along a second direction opposite to the first direction. The sliding strip 50 is thereby located in a first position, where each of the two latching hooks 51 is engaged with a flange of each of the two latching holes 111 to prevent the display frame 40 from rotating relative to the base 10, and the resilient member 70 has a first elastic deformation.

When the display frame 40 needs to be open, the operating portion 61 of the actuating member 60 is pushed along the first direction. The sliding strip 50 is slid relative to the display frame 40 in the first direction along the actuating member 60. The sliding strip 50 is thereby located in a second position, where each of the two latching hooks 51 is disengaged from the flange of each of the two latching holes 111, and the second elastic deformation is greater than the first elastic deformation. The display frame 40 is rotated in succession, until each of the two latching hooks 51 is disengaged from each of the latching holes 111.

It is to be understood, however, that even though numerous characteristics and advantages have been set forth in the foregoing description of embodiments, together with details of the structures and functions of the embodiments, the disclosure is illustrative only and changes may be made in detail, especially in the matters of shape, size, and arrangement of parts within the principles of the disclosure to the full extent indicated by the broad general meaning of the terms in which the appended claims are expressed.

What is claimed is:

1. An electronic device enclosure, comprising:
a base defining two latching holes;
a display frame rotatably secured to the base; and
a locking structure comprising a sliding strip and a resilient member, the sliding strip being attached on the display frame and comprising two latching hooks, and the resilient member being hung between the display frame and the sliding strip;
wherein the sliding strip is slidable relative to the display frame between a first position and a second position; when the sliding strip is located in the first position, each of the two latching hooks is engaged with each of the latching holes, to prevent the display frame from rotating relative to the base; when the sliding strip is located in the second position, each of the two latching hooks is disengaged from each of the two latching holes; and the resilient member is resiliently deformable to slide the sliding strip from the second position to the first position.

2. The electronic device enclosure of claim 1, wherein when the sliding strip is located in the first position, the resilient member has a first elastic deformation; and when the sliding strip is located in the second position, the resilient member has a second elastic deformation, and the second elastic deformation is greater than the first elastic deformation.

3. The electronic device enclosure of claim 1, wherein the locking structure further comprises an actuating member, the actuating member is engaged with the display frame and the sliding strip and configured to bias the sliding strip from the first position to the second position.

4. The electronic device enclosure of claim 3, wherein the sliding strip further comprises a strip body and two resisting tabs located on the strip body, the display frame defines two installation holes; and the actuating member comprises two engaging hooks, and each of the two engaging hooks extends through each of the two installation holes to be engaged with each of the two resisting tabs.

5. The electronic device enclosure of claim 4, wherein the strip body defines two receiving holes, and each of the two resilient tabs extends from one sidewall of each of the two receiving holes.

6. The electronic device enclosure of claim 4, wherein the two latching hooks are located on the strip body and in a first plane, the two resisting tabs are located in a second plane, and the first plane is substantially perpendicular to the second plane.

7. The electronic device enclosure of claim 4, wherein the display frame defines a recess in communication with the installation holes, the actuating member further comprises an operating portion connected to the engaging hooks, and the operating portion is slidably received in the recess.

8. The electronic device enclosure of claim 4, wherein the display frame comprises a backboard, two pairs of latching structures are located on the backboard, and two opposite ends of the sliding strip are engaged with the two pairs of the latching structures.

9. The electronic device enclosure of claim 8, wherein a limiting tab is located on the backboard, when the sliding strip is located in the first position, one end of the sliding strip abuts the limiting tab; and when the sliding strip is located in the second position, the one end of the sliding strip is disengaged from the limiting tab.

10. The electronic device enclosure of claim 8, wherein a first stopper hook is located on the backboard, a second hook is located on the strip body, and a first end of the resilient member is hang on the first stopper hook, and a second end opposite to the first end is hang on the second stopper hook.

11. An electronic device enclosure, comprising:
a base defining two latching holes;
a display frame rotatably secured to the base; and
a locking structure comprising a sliding strip and a resilient member, the sliding strip being attached on the display frame and comprising two latching hooks, and the resilient member being hung between the display frame and the sliding strip;
wherein each of the two latching hooks is engaged with each of the two latching holes, to prevent the display frame from rotating relative to the base, and the resilient member is hung between the display frame and the sliding strip and resiliently deformed, to prevent each of the two latching hooks from disengaging from the two latching holes.

12. The electronic device enclosure of claim 11, wherein the sliding strip is slidable relative to the display frame between a first position and a second position; when the sliding strip is located in the first position, the resilient member has a first elastic deformation; when the sliding strip is located in the second position, the resilient member has a second elastic deformation, and the second elastic deformation is greater than the first elastic deformation.

13. The electronic device enclosure of claim 12, wherein the locking structure further comprises an actuating member, the actuating member is engaged with the display frame and the sliding strip and configured to bias the sliding strip from the first position to the second position.

14. The electronic device enclosure of claim 13, wherein the sliding strip further comprises a strip body and two resisting tabs located on the strip body, the display frame define two installation holes; the actuating member comprises two engaging hooks, and each of the two engaging hooks extends through each of the two installation holes to be engaged with each of the two resisting tabs.

15. The electronic device enclosure of claim 14, wherein the strip body defines two receiving holes, and each of the two resilient tabs extends from one sidewall of each of the two receiving holes.

16. The electronic device enclosure of claim 14, wherein the two latching hooks are located on the strip body and in a first plane, the two resisting tabs are locate in a second plane, and the first plane is substantially perpendicular to the second plane.

17. The electronic device enclosure of claim 14, wherein the display frame defines a recess in communication with the installation holes, the actuating member further comprises an operating portion connected to the engaging hooks, and the operating portion is slidably received in the recess.

18. The electronic device enclosure of claim 14, wherein the display frame comprises a backboard, two pairs of latching structures are located on the backboard, and two opposite ends of the sliding strip are engaged with the two pairs of the latching structures.

19. The electronic device enclosure of claim 18, wherein a limiting tab is located on the backboard, the sliding strip is slidable along a first direction to disengage from the limiting tab, and along a second direction opposite to the first direction to abut the limiting tab.

20. The electronic device enclosure of claim 18, wherein a first stopper hook is located on the backboard, a second hook is located on the strip body, and a first end of the resilient member is hung on the first stopper hook, and a second end opposite to the first end is hung on the second stopper hook.
